(19) United States
(12) Patent Application Publication
(10) Pub. No.: US 2016/0189983 A1
(43) Pub. Date: Jun. 30, 2016

(54) METHOD AND STRUCTURE FOR FAN-OUT WAFER LEVEL PACKAGING

(71) Applicant: NANTONG FUJITSU MICROELECTRONICS CO., LTD., NANTONG (CN)

(72) Inventor: Lei Shi, Nantong (CN)

(73) Assignee: NANTONG FUJITSU MICROELECTRONICS CO., LTD.

(21) Appl. No.: 14/975,894

(22) Filed: Dec. 21, 2015

(30) Foreign Application Priority Data
Dec. 24, 2014 (CN) 2014-10818160.7

(51) Int. Cl. H01L 21/56; H01L 23/00; H01L 23/498; H01L 23/31

(52) U.S. Cl. CPC H01L 21/561; H01L 21/568; H01L 23/3114; H01L 24/17; H01L 23/49816; H01L 2924/0105

(57) ABSTRACT

A method for fan-out wafer level chip packaging includes: providing a carrier substrate; forming a plurality of conductive base layers on a surface of the carrier substrate; mounting a plurality of chips on the conductive base layers and electrically connecting the chips to the conductive base layers by using a plurality of wire leads; forming a packaging layer to encapsulate the chips, the wire leads, the conductive base layers, and a top surface of the carrier substrate; removing the carrier substrate; and forming a plurality of conductive layers on bottom surfaces of the conductive base layers.

### CROSS-REFERENCES TO RELATED APPLICATIONS

This application claims the priority of Chinese Patent Application No. CN201410818160.7, filed on Dec. 24, 2014, the entire content of which is incorporated herein by reference.

### FIELD OF THE DISCLOSURE

The present disclosure generally relates to the field of integrated circuit packaging technology and, more particularly, relates to a method and a structure for fan-out wafer level packaging.

### BACKGROUND

In current semiconductor industry, electronic packaging has become an important aspect of the development of the industry. Decades of development of packaging technology has come to a stage where demands on packaging high-density and small-sized electronics become the mainstream direction of the packaging technology. Fan-out wafer level packaging (FOWLP) is an embedded type packaging method during wafer level processing and is also a major advanced packaging technology for packaging a large quantity of inputs and outputs (I/O) with high integration flexibility.

In addition, the FOWLP technology can realize multiple-chip integration along vertical and horizontal directions in a single package without using a substrate. Therefore, the FOWLP technology is now being developed into a next-generation packaging technology, such as multiple-chip packaging, low profile packaging, 3D system-in package, etc. As electronic products are developed to be thinner and lighter with a higher pin density and a lower cost, single-chip packaging technology has gradually become unable to meet the industry needs. The emergence of a new packaging technology, i.e., wafer level packaging technology, provides an opportunity to develop low-cost packaging for the packaging industry.

Currently, wafer level fan-out packaging structure uses a method of wafer reconstruction and wafer level redistribution to realize packaging of fan-out structure of chips, and the wafer level fan-out packaging structure is then cut to eventually form individual single packages. However, according to the present disclosure, several aspects of the existing methods still need to be further improved.

First, the fan-out structure in current packaging technology is relatively specialized and application of the fan-out structure is not wide enough. Second, the density of the I/O terminals is relatively small. Third, the existing methods are not conducive to reduce product cost.

For example, a wafer level chip packaging method disclosed in Chinese Patent No. CN10288164A includes following steps: Step 1, a wafer containing a plurality of chip bodies is provided with each chip body having integrated chip electrodes and chip sensing areas; Step 2, a cover plate is attached to the wafer through an isolation layer by performing a wafer bonding process; Step 3, the bonded structure of the cover plate, the isolation layer and the wafer is flipped by 180° and then a polishing, a dry etching, or a wet etching process is performed on the back side of the wafer to reduce the thickness of the wafer to a preset value; Step 4, horn-shaped silicon vias are formed in the wafer by sequentially performing a photolithography process, a dry etching process, a photo-resist removal process, and another dry etching process to have the top of each silicon via reaching the bottom surface of the corresponding chip electrode; Step 5, an insulating layer is formed in the silicon vias and the bottom surface of the chip bodies by using a chemical vapor deposition (CVD) method; Step 6, a dry etching process is performed on the insulating layer to expose the bottom surface of each chip electrode; Step 7, a metal wire layer is formed on the bottom surface of each chip electrode and the surface of the insulating layer by sequentially performing a sputtering process, a photolithography process, an electroplating process, a photo-resist removal process, and a metal etching process, or by sequentially performing a sputtering process, a photolithography process, a metal etching process, and an electroless plating process; Step 8, a wire protection layer is formed to selectively cover a portion of the insulating layer and the metal wire layer, then solder material is printed or plated, or an initial soldering ball is planted, onto an area of each metal wire layer exposed through the wire protection layer, and finally, a solder ball connecting to the metal wire layer is formed by back flowing the soldering material or the initial soldering ball; and Step 9, the packaged wafer is then cut to form individual wafer level horn-shaped chip packaging structures.

The above method introduces a cover plate during the packaging process. However, the cover plate is not removed from the ultimate packaged structure. Therefore, the disclosed method is not conducive to reducing the product cost, applying to various packaging forms, or achieving a relatively high accuracy.

For another example, a microelectromechanical system (MEMS) wafer level packaging structure and packaging method disclosed in Chinese Patent No. CN103552977A describes a packaging method including the following steps.

First, an optical glass and an epoxy substrate are provided. The epoxy substrate is cut into a round plate with a shape and a size consistent with the shape and the size of the wafer to be packaged. A plurality of through holes are formed in the epoxy round plate with the position of each through hole corresponding to the position of each chip on the wafer.

Further, the wafer, the epoxy round plate, and the optical glass are pressed together in the order with the integrated circuit (IC) side of the wafer facing to the epoxy round plate and the position of each IC on the wafer corresponding to the position of a through hole in the epoxy round plate.

In the above method, epoxy is used as the packaging material. However, the strength of the epoxy is relatively low, thus the material may not provide sufficient support for the fan-out structure to be packaged. Therefore, epoxy may not be applicable to thin structure packaging. In addition, because of the relatively small density of the I/O terminals, offset of chips to be packaged may likely occur during the packaging process.

The disclosed method and structure for fan-out wafer level packaging are directed to solve one or more problems set forth above and other problems in the art.

### BRIEF SUMMARY OF THE DISCLOSURE

One aspect of the present disclosure includes a method for fan-out wafer level chip packaging. The method includes: providing a carrier substrate; forming a plurality of conductive base layers on a surface of the carrier substrate; mounting a plurality of chips on the conductive base layers and electrically connecting the chips to the conductive base layers by using a plurality of wire leads; forming a packaging layer to encapsulate the chips, the wire leads, the conductive base layers, and a top surface of the carrier substrate; removing the carrier substrate; and forming a plurality of conductive layers on bottom surfaces of the conductive base layers.

Another aspect of the present disclosure provides another method for fan-out wafer level chip packaging. The method includes: providing a carrier substrate; forming a plurality of soldering pads on a surface of the carrier substrate; mounting a plurality of chips on the soldering pads with an active side of each chip facing to the carrier substrate; forming a packaging layer to encapsulate the chips, the soldering pads, and the surface of the carrier substrate; removing the carrier substrate; and forming a plurality of conductive layers on bottom surfaces of the soldering pads.

Another aspect of the present disclosure provides a fan-out wafer level packaged chip structure. The fan-out wafer level packaged chip structure includes a chip, a plurality of soldering pads, a plurality of conductive layers, a plurality of dielectric layers, a plurality of soldering balls, and a packaging layer. The chip is mounted on the soldering pads with an active side of the chip facing the soldering pads. The packaging layer encapsulates the chip, the soldering pads, and top surfaces of the dielectric layers and the conductive layers. Each conductive layer is electrically connected to a corresponding soldering pad. The dielectric layers fill the spaces between the conductive layers. Each soldering ball is formed on a bottom surface of the corresponding conductive layer.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic view of an exemplary carrier substrate consistent with disclosed embodiments of the present disclosure;

FIG. 2 illustrates a schematic view of a structure with a plurality of conductive base layers and a patterned film layer formed on the carrier substrate according to disclosed embodiments;

FIG. 3 illustrates a schematic view of a structure with only the plurality of conductive base layers left on the carrier substrate after removing the film layer according to disclosed embodiments;

FIG. 4 illustrates a schematic view of a structure with a plurality of bonding layers formed on a plurality of selected conductive base layers according to disclosed embodiments;

FIG. 5 illustrates a schematic view of a packaged structure according disclosed embodiments;

FIG. 6 illustrates a schematic diagram for removing the carrier substrate according to disclosed embodiments;

FIG. 7 illustrates a schematic view of a structure with a plurality of dielectric layer formed on the bottom of the packaged structure according to disclosed embodiments;

FIG. 8 illustrates a schematic view of a structure with a plurality of dielectric layers and a plurality of conductive layers formed on the bottom of the packaged structure according to disclosed embodiments;

FIG. 9 illustrates a schematic view of a structure with a plurality of soldering balls formed on the bottom of the packaged structure according to disclosed embodiments;

FIG. 10 illustrates a schematic view of a structure with a plurality of soldering pads formed on a carrier substrate according to another disclosed embodiment;

FIG. 11 illustrates a schematic view of a structure with semiconductor chips flipped and mounted on soldering pads while the gaps between the chips and the carrier substrate filled with packaging material according to another disclosed embodiment;

FIG. 12 illustrates a schematic view of a packaged structure according to another disclosed embodiment;

FIG. 13 illustrates a schematic diagram for removing the carrier substrate according to another disclosed embodiment;

FIG. 14 illustrates a schematic view of a structure with a plurality of dielectric layer formed on the bottom of the packaged structure according to another disclosed embodiment;

FIG. 15 illustrates a schematic view of a structure with a plurality of dielectric layers and a plurality of conductive layers formed on the bottom of the packaged structure according to another disclosed embodiment;

FIG. 16 illustrates a schematic view of a structure with a plurality of soldering balls formed on the bottom of the packaged structure according to another disclosed embodiment;

FIG. 17 illustrates a schematic view of an individual packaged semiconductor structure consistent with another disclosed embodiment;

FIG. 18 illustrates a flowchart of an exemplary packaging method consistent with disclosed embodiments; and

FIG. 19 illustrates a flowchart of an exemplary packaging method consistent with another disclosed embodiment.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

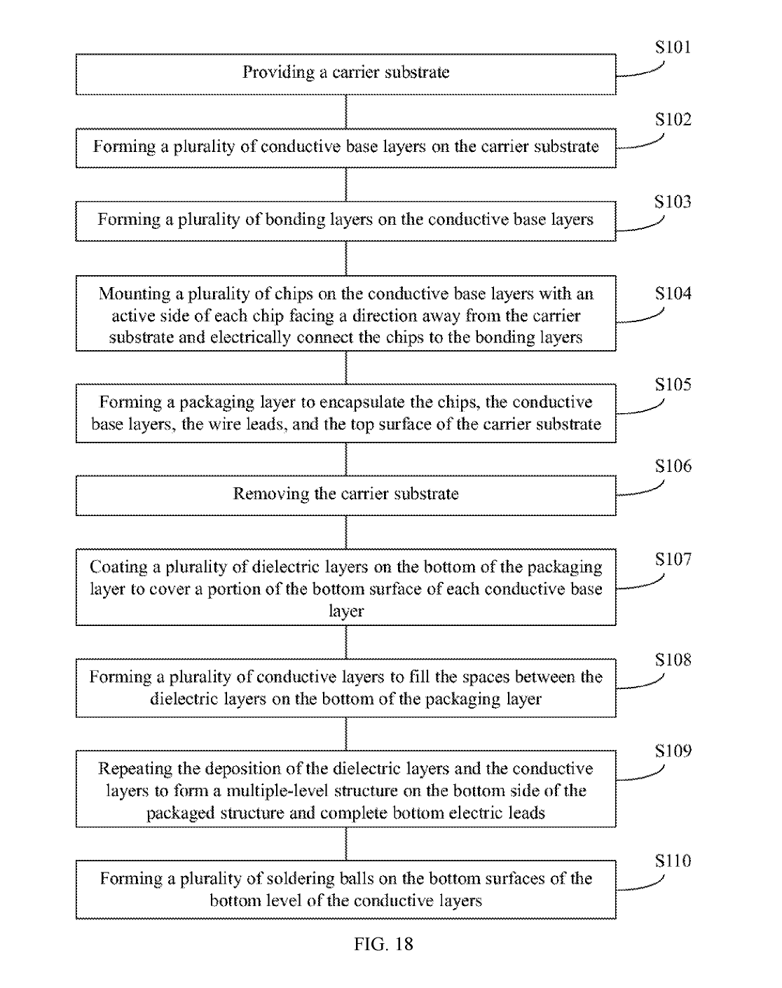

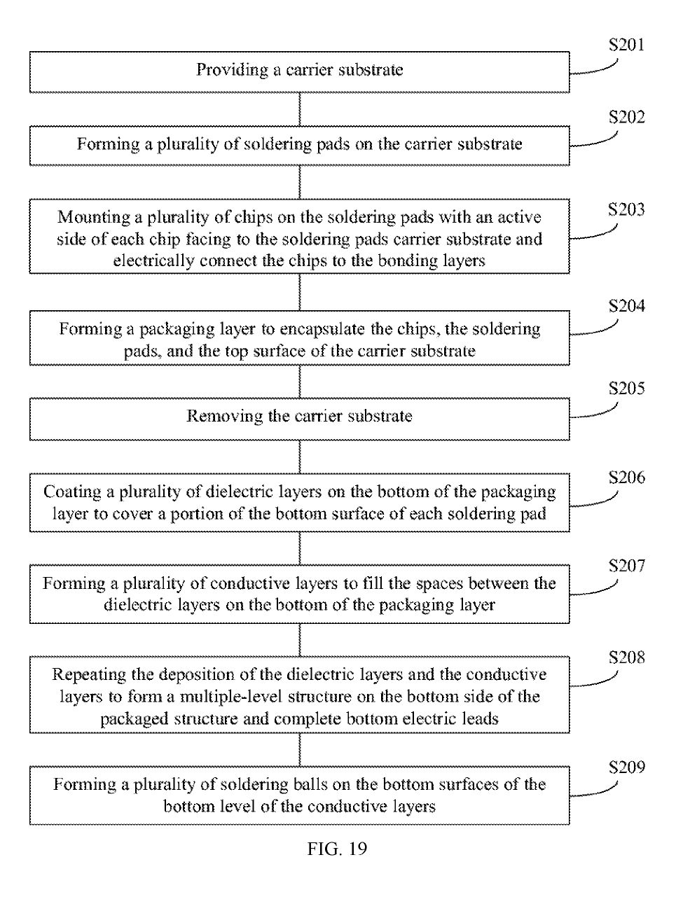

The present disclosure provides a fan-out wafer level packaging method to solve one or more problems set forth above and other problems in the existing methods. FIG. 18 shows a flowchart of an exemplary fan-out wafer level packaging method consistent with disclosed embodiments.

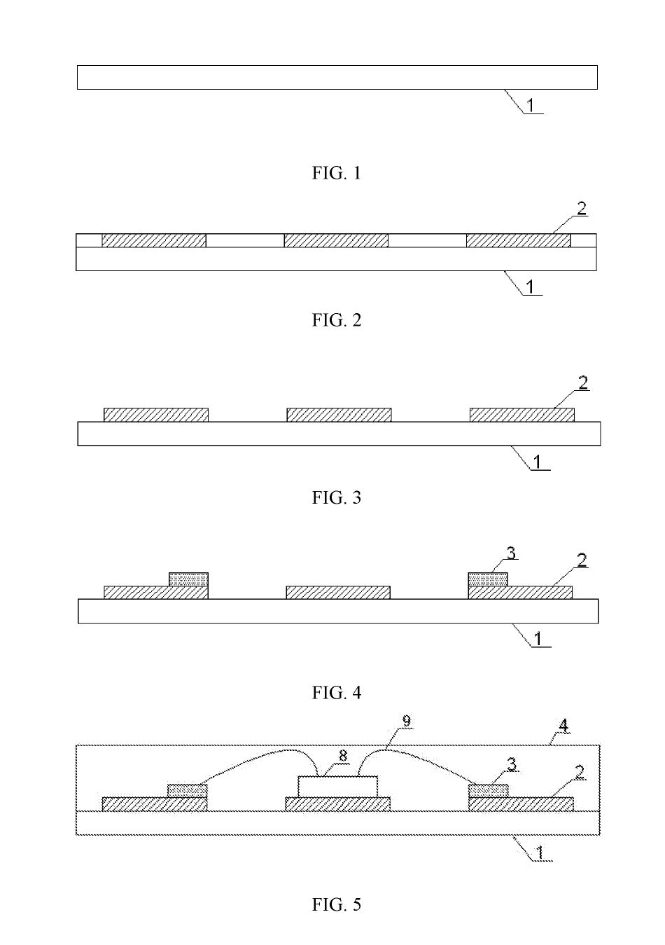

Referring to FIG. 18, at the beginning of the packaging process, a carrier substrate is provided (S101). FIG. 1 shows a schematic view of the carrier substrate 1. The carrier substrate 1 may be made of glass, silicon, or a ceramic material.

Returning to FIG. 18, further, a plurality of conductive base layers may be formed on the carrier substrate (S102). FIG. 3 shows a schematic view of the corresponding structure.

As shown in FIG. 3, the conductive base layers 2 may be made from a metal coating layer. Specifically, first, the metal coating layer may be formed on the carrier substrate 1 by electroplating, electroless plating, or sputtering. Then, a film layer may be coated on the surface of substrate having the metal coating layer formed on. The film layer may be formed into a certain shape. The film layer may be made of a photo-resist material, and accordingly, the certain shape of the film layer may be achieved by performing an exposure and develop process to remove a portion of the film layer. A portion of the metal coating layer may then be exposed. Further, by performing an exposure and develop process or an etching process, the portion of the exposed metal coating layer may be removed. Finally, the film layer may be removed to form the plurality of conductive base layers 2. The film layer may be removed by a photolithography or a chemical etching process.

In certain other embodiments, coating a conductive base material and forming a film layer may have a reversed order. That is, first, the film layer may be coated on a surface of the carrier substrate. The film layer may be formed into a certain shape. Then, the conductive base material may be coated on the surface of the substrate with the film layer coated on. A portion of the coated conductive base material may then be removed by a photolithography process to form the conductive base layers. FIG. 2 shows a corresponding structure. Finally, the film layer may be completely removed.

Further, returning to FIG. 18, a plurality of bonding layers may be formed on the top of the conductive base layers (S103). FIG. 4 shows a schematic view of the corresponding structure. Referring to FIG. 4, the plurality of bonding layers 3 may be selectively formed on the conductive base layers 2. That is, some conductive base layers 2 may not have a bonding layer 3 formed on. The bonding layer 3 may be made of Ag, Pd, or an alloy of Ag and Pd.

Further, a plurality of semiconductor chips may be mounted on the conductive base layers with an active side of each chip facing a direction away from the carrier substrate and the chips may be electrically connected to the bonding layers (S104). A schematic view of the structure is shown FIG. 5. Referring to FIG. 5, the chip 8 is mounted on a conductive base layer 2 without a bonding layer 3 formed on. The active side of the chip 8 is a far side from the carrier substrate 1. The chip 8 is electrically connected to the bonding layers 3 by wire leads 9.

Further, returning to FIG. 18, the chips, the wire leads, the conductive base layers, and the carrier substrate may be packaged by using a filling material (S105). FIG. 5 shows a schematic view of the packaged structure. Referring to FIG. 5, a packaging layer 4 is formed by a filling material to encapsulate the chip 8, the wire leads 9, the conductive base layers 2, and the top side of the carrier substrate 1. Optionally, the filling material may be non-epoxy resins. For example, the filling material may be one or more of phenolic resin, unsaturated resin-based polymer, etc.

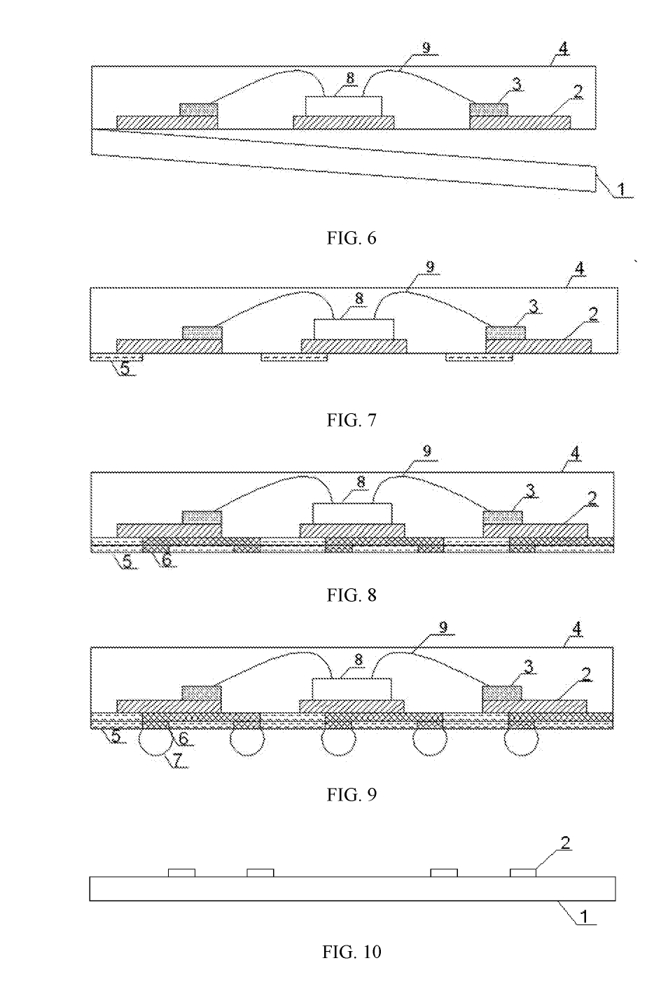

Then, returning to FIG. 18, the carrier substrate may be removed (S106). FIG. 6 shows a schematic diagram for removing the carrier substrate 1. Referring to FIG. 6, the carrier substrate 1 may be removed by a photolithography, chemical etching, or mechanical thinning process.

Further, returning to FIG. 18, a plurality of dielectric layers may be coated onto the bottom of the packaging layer and the conductive base layers (S107). FIG. 7 shows a schematic view of the corresponding structure. Referring to FIG. 7, the plurality of dielectric layers 5 are formed on the bottom surface of the packaging layer 4 and the conductive base layers 2. Optionally, each dielectric layer 5 covers a portion of each conductive base layer 2. That is, each dielectric layer 5 is coated on a portion of the corresponding conductive base layer 2 while the dielectric layer 5 also covers a portion of the packaging layer 4. The dielectric layer 5 may be made of an organic insulating polymeric material.

Further, a plurality of conductive layers may be filled into the trenches formed by the dielectric layers, the conductive base layers, and the packaging layer (S108). Referring to FIG. 8, each conductive layer 6 is formed between two neighboring dielectric layers 5 to cover a portion of the bottom surface of the corresponding conductive base layer 2 and the packaging layer 4. Each conductive layer 6 is electrically connected to the corresponding conductive base layer 2. The conductive layers 6 may be made of Cu or Cu alloy. The conductive layers 6 may be formed by any appropriate process. For example, the conductive layers 6 may be formed by a sputtering process with a mask covering the dielectric layers 5.

The dielectric layers and the conductive layers may have a single-level or a multiple-level structure. When the dielectric layers and the conductive layers have multiple levels, the above process to form a single level of dielectric layers and conductive layers may be repeated to complete the multiple-level structure. The conductive layers are electrically connected with each other through all the levels and form bottom electric leads for the corresponding conductive base layers. In addition, conductive layers of different levels may form tilted bottom electric leads. That is, the bottom electric leads may not vertically point to the corresponding conductive base layers and, thus, the conductive layers at the final level may distributed more uniformly on the bottom surface of the packaged structure. With the conductive layers spread more uniformly on the surface of the packaged structure, ball-planting in a subsequent process may be easy.

In one embodiment, returning to FIG. 18, another level of the dielectric layers and the conductive layers may be coated on the bottom side of the packaged structure to form a multiple-level structure and complete bottom electric leads (S109). FIG. 8 shows a schematic view of the corresponding structure with complete bottom electric leads.

Referring to FIG. 8, another level of the dielectric layers 5 may be formed on the bottom of the packaged structure. Each dielectric layer 5 may cover a portion of the bottom surface under each conductive base layer 2. Then, another level of the conductive layers 6 may be formed to fill the spaces between the dielectric layers 5. The multiple levels of the conductive layers 6 may be tightly linked with each other to form the bottom electric leads.

Further, returning to FIG. 18, a plurality of soldering balls may be formed on the bottom surfaces of the bottom level of the conductive layers (S110). FIG. 9 shows a schematic view of the corresponding structure with soldering balls 7 formed on the conductive layers 6 at the bottom of the packaged structure. The soldering material may be Sn.

Of course, the packaged structure may be further thinned and cut in order to form individual fan-out wafer level packaging structures. Specifically, thinning the packaged structure may be performed prior to the formation of the soldering balls 7 while cutting the packaged structure into individual fan-out wafer level packaged chip structure may be performed after the formation of the soldering balls 7.

FIG. 19 shows a flowchart of an exemplary fan-out wafer level packaging method consistent with disclosed embodiments.

Referring to FIG. 19, at the beginning of the packaging process, a carrier substrate is provided (S201). The carrier substrate 1 may be made of glass, silicon, or a ceramic material.

Further, a plurality of soldering pads may be formed on the carrier substrate (S202). FIG. 10 shows a schematic view of the corresponding structure. Referring to FIG. 10, the plurality soldering pads 2 are formed on the top surface of the carrier substrate 1. The soldering pads 2 may be made of any appropriate conductive material.

Further, returning to FIG. 19, semiconductor chips may be mounted on the soldering pads with active sides of the chips facing to the soldering pads (S203). FIG. 11 shows a schematic view of the structure with semiconductor chips 8 mounted on the soldering pads 2. Moreover, electrodes in the chips 8 may be electrically connected to corresponding soldering pads 2 by soldering balls arranged between the chips 8 and the soldering pads 2.

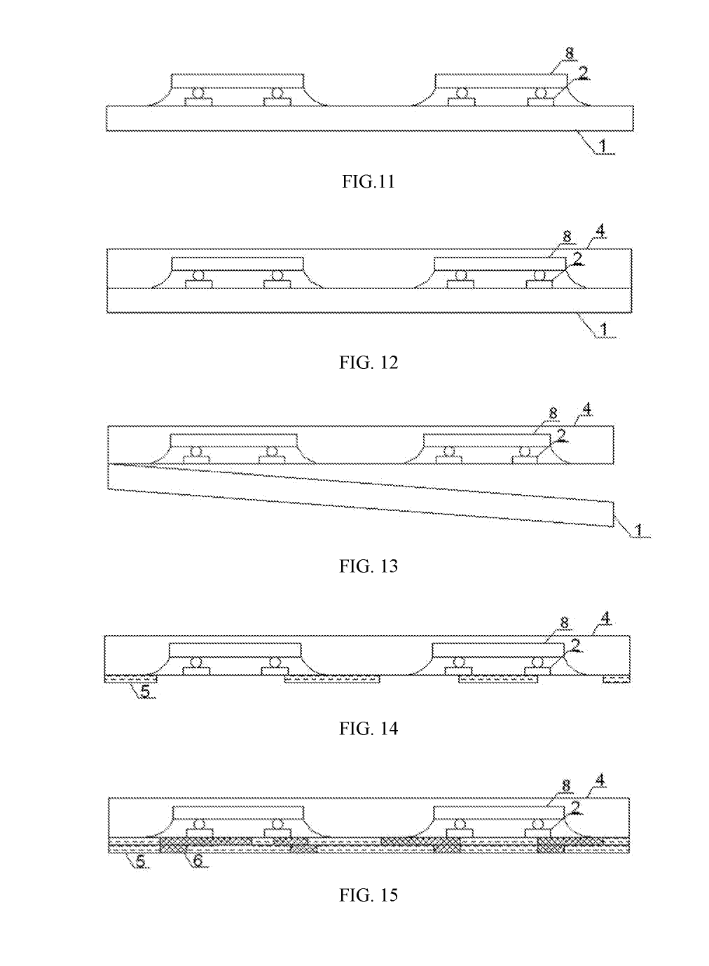

Further, returning to FIG. 19, the chips and the carrier substrate may be packaged by using a filling material (S204). Optionally, the filling material may only be filled into a space between each chip 8 and the carrier substrate 1. FIG. 11 shows the corresponding structure with the filling material only occupying the space between each chip 8 and the carrier substrate 1. Optionally, the filling material may be further filled to form a packaging layer 4 completely encapsulating the chips 8, the soldering pads 2, and the top surface of the carrier substrate 1. FIG. 12 shows a schematic view of the corresponding packaged structure with the packaging layer 4. The filling material may be non-epoxy resins. For example, the filling material may be one or more of phenolic resin, unsaturated resin-based polymer, etc.

Further, returning to FIG. 19, the carrier substrate may be removed (S205). FIG. 13 shows a schematic diagram to remove the carrier substrate 1. The carrier substrate 1 may be removed by a photolithography, chemical etching, or mechanical thinning process.

Further, a plurality of dielectric layers may be coated onto the bottom of the packaging layer and the soldering pads (S206). FIG. 14 shows a schematic view of the corresponding structure. Referring to FIG. 14, the plurality of dielectric layers 5 are formed on the bottom surface of the packaging layer 4 and the soldering pads 2. Each dielectric layer 5 covers a portion of each soldering pad 2. That is, each dielectric layer 5 is coated on a portion of the corresponding soldering pad 2 while also covers a portion of the packaging layer 4. The dielectric layer 5 may be made of an organic insulating polymeric material.

Further, returning to FIG. 19, a plurality of conductive layers may be filled into the trenches formed by the dielectric layers, the soldering pads, and the packaging layer (S207). Referring to FIG. 15, each conductive layer 6 is formed between two neighboring dielectric layers 5 and on a portion of the bottom surface of the corresponding soldering pad 2 and the packaging layer 4. Each conductive layer 6 is electrically connected to the corresponding soldering pad 2. The conductive layers 6 may be made of Cu or its alloy. The conductive layers 6 may be formed by any appropriate process. For example, the conductive layers 6 may be formed by a sputtering process with a mask covering the dielectric layers 5.

The dielectric layers and the conductive layers may have a single-level or a multiple-level structure. When the dielectric layers and the conductive layers have multiple levels, the above process to form a single level of dielectric layers and conductive layers may be repeated to complete the multiple-level structure. The conductive layers are electrically connected with each other through all the levels and form bottom electric leads for the corresponding soldering pads. In addition, conductive layers of different levels may form tilted bottom electric leads. That is, the bottom electric leads may not vertically point to the corresponding soldering pads and, thus, the conductive layers at the final level may distributed more uniformly on the bottom surface of the packaged structure. With the conductive layers spread more uniformly on the surface of the packaged structure, ball-planting in a subsequent process may be easy.

In one embodiment, returning to FIG. 19, another level of the dielectric layers and the conductive layers may be coated on the bottom side of the packaged structure to form a multiple-level structure and complete a bottom electric leads (S208). FIG. 15 shows a schematic view of the corresponding structure with complete bottom electric leads. Referring to FIG. 15, another level of the dielectric layers 5 may be formed on the bottom of the packaged structure. Each dielectric layer 5 may cover a portion of the bottom surface under each soldering pad 2. Then, another level of the conductive layers 6 may be formed to fill the spaces between the dielectric layers 5. The multiple levels of the conductive layers 6 may be tightly linked with each other to form the bottom electric leads.

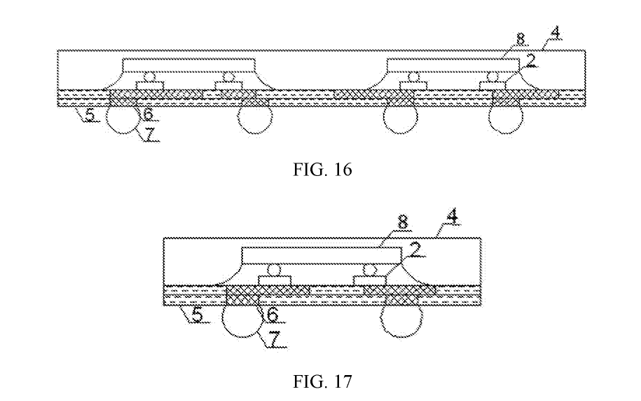

Further, returning to FIG. 19, a plurality of soldering balls may be formed on the bottom surfaces of the bottom level of the conductive layers (S209). FIG. 16 shows a schematic view of the corresponding structure with soldering balls 7 formed on the conductive layers 6 at the bottom of the packaged structure. The soldering material may be Sn.

Of course, the packaged structure may be further thinned and cut in order to form individual fan-out wafer level packaging structures. Specifically, thinning the packaged structure may be performed prior to the formation of the soldering balls 7 while cutting the packaged structure into individual fan-out wafer level packaged chip structure may be performed after the formation of the soldering balls 7.

The present disclosure also provides a packaged semiconductor structure. FIG. 17 shows a schematic view of a packaged exemplary semiconductor structure consistent with disclosed embodiments.

Referring to FIG. 17, the packaged semiconductor structure includes a plurality of soldering pads 2, a chip 8, a plurality of conductive layers 6, a plurality of dielectric layer 5, a plurality of soldering balls 7, and a packaging layer 4.

The chip 8 is mounted on the soldering pads with an active side of the chip facing to the soldering pads. The packaging layer 4 is formed by using filling material to encapsulate the chip 8, the soldering pads 2, and the top surface of the conductive layers 6 and the dielectric layers. The packaging layer 4 may be made of non-epoxy resins such as phenolic resin, unsaturated resin-based polymer, etc. The conductive layers 6 are connecting to the soldering pads 2 and the conductive layers 6 may have a single-level or a multiple-level structure. When the conductive layers 6 have a multiple-level structure, the multiple levels of the conductive layer 6 are electrically connected with each other to form bottom electric leads. The conductive layers 6 may be made of Cu or its alloy. Further soldering balls 7 may be formed on the bottom level of the conductive layer 6. The soldering balls 7 may be made of Sn.

Fan-out wafer level packaged chip 8 obtained by using the disclosed method has a packaging layer covering the chip. The material used to form the packaging layer is a phenolic resin or an unsaturated resin-based polymer, which has relatively strong strength. Therefore, the packaging material may provide enhanced support strength for the fan-out structure and, thus, the packaging material may be applicable to thin structure packaging. In addition, the fan-out structure in the present disclosure may have a variety of forms and thus may have a broad application scope. Further, the content of Cu used in the packaged structure may be reduced, thus conducive to reducing the product cost. Moreover, in the disclosed packaged chip, the density of the I/O terminals is usually not low. Finally, by removing the carrier substrate 1 and then forming electric leads on the bottom of the structure, the disclosed method may be conducive to reducing the product cost, applying to various packaging forms, and achieving a relatively high accuracy. In the meantime, the distance between soldering balls may be decreased, the content of Cu used in the electric leads may be significantly reduced, and the support strength for the structure may be reinforced.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fan-out wafer level chip packaging, comprising:
providing a carrier substrate;
forming a plurality of conductive base layers on a surface of the carrier substrate;
mounting a plurality of chips on the conductive base layers and electrically connecting the chips to the conductive base layers by using a plurality of wire leads;
forming a packaging layer to encapsulate the chips, the wire leads, the conductive base layers, and a top surface of the carrier substrate;
removing the carrier substrate; and
forming a plurality of conductive layers on bottom surfaces of the conductive base layers.

2. The method for fan-out wafer level chip packaging according to claim 1, wherein the plurality of conductive base layers are formed on the carrier substrate by a process including:
coating a conductive base material onto the top surface of the carrier substrate;
coating a film layer on the surface of the carrier substrate with the conductive base material coated on;
removing a portion of the film layer by performing an exposure and develop process to expose a portion of the coated conductive base material;
removing the exposed portion of the coated conductive base material to form the plurality of conductive base layers; and
removing the other portion of the film layer.

3. The method for fan-out wafer level chip packaging according to claim 1, wherein the plurality of conductive base layers are formed on the carrier substrate by a process including:
coating a film layer on the top surface of the carrier substrate;
removing a portion of the film layer by performing an exposure and develop process to expose the surface of the carrier substrate;
coating a conductive base material onto the top surface of the carrier substrate; and
removing a portion of the coated conductive base material and a portion of the film layer to form the plurality of conductive base layers.

4. The method for fan-out wafer level chip packaging according to claim 1, wherein:
a plurality of bonding layers are formed on the conductive base layers.

5. The method for fan-out wafer level chip packaging according to claim 4, wherein:
the chips are mounted on the conductive base layers with an active side of each chip facing to a direction away from the carrier substrate; and
the chips are electrically connected to the bonding layers on the conductive base layers by using the wire leads.

6. The method for fan-out wafer level chip packaging according to claim 5, wherein prior to forming the plurality of conductive layers, further including:
forming a plurality of dielectric layers to cover a portion of a bottom surface of each conductive base layer and a portion of a bottom surface of the packaging layer.

7. The method for fan-out wafer level chip packaging according to claim 6, wherein:
forming a plurality of the conductive layers to fill trenches formed by the dielectric layers, the conductive base layers, and the packaging layer; and
each conductive layers is electrically connected to the corresponding conductive base layer.

8. The method for fan-out wafer level chip packaging according to claim 7, wherein the conductive layers have a single-level or multiple-level structure.

9. The method for fan-out wafer level chip packaging according to claim 8, wherein forming the multiple-level conductive layers further includes:
coating a plurality of dielectric layers on the bottom side of the packaging layer with each dielectric layer covering a portion of a surface area corresponding to each conductive base layer;
forming a plurality of the conductive layers to fill into trenches formed between neighboring dielectric layers; and
repeating the above processes until all levels of conductive layers are formed, wherein:
the multiple levels of conductive layers are tightly linked with each other to form bottom electric leads connected to the conductive base layers.

10. The method for fan-out wafer level chip packaging according to claim 9, wherein further including:
thinning the packaged structure from the bottom surface of the packaging layer;
forming soldering balls on bottom surfaces of the conductive layers; and
cutting the packaged structure to form a plurality of individual fan-out wafer level packaged chip structures.

11. A method for fan-out wafer level chip packaging, comprising:
providing a carrier substrate;
forming a plurality of soldering pads on a surface of the carrier substrate;
providing a plurality of chips;
mounting the chips on the soldering pads with an active side of each chip facing to the carrier substrate;
forming a packaging layer to encapsulate the chips, the soldering pads, and the surface of the carrier substrate;
removing the carrier substrate;
forming a plurality of dielectric layers on a bottom surface of the packaging layer to cover a portion of a bottom surface of each soldering pad; and
forming a plurality of conductive layers between neighboring dielectric layers on the bottom of the packaging layer.

12. The method for fan-out wafer level chip packaging according to claim 11, wherein the conductive layers have a single-level or multiple-level structure.

13. The method for fan-out wafer level chip packaging according to claim 12, wherein forming the multiple-level conductive layers further includes:
coating a plurality of dielectric layers on the bottom side of the packaging layer with each dielectric layer covering a portion of a surface area corresponding to each soldering pad;
forming a plurality of the conductive layers to fill into trenches formed between neighboring dielectric layers; and
repeating the above processes until all levels of conductive layers are formed, wherein:
the multiple levels of conductive layers are tightly linked with each other to form bottom electric leads connected to the soldering pads.

14. The method for fan-out wafer level chip packaging according to claim 13, wherein further including:
thinning the packaged structure from the bottom surface of the packaging layer;
forming soldering balls on bottom surfaces of the conductive layers; and
cutting the packaged structure to form a plurality of individual fan-out wafer level packaged chip structures.

15. A fan-out wafer level packaged chip structure, comprising:
a chip;
a plurality of soldering pads;
a plurality of conductive layers;
a plurality of dielectric layers;
a plurality of soldering balls; and
a packaging layer, wherein:
the chip is mounted on the soldering pads with an active side of the chip facing the soldering pads;
the packaging layer encapsulates the chip, the soldering pads, and top surfaces of the dielectric layers and the conductive layers;
each conductive layer is electrically connected to a corresponding soldering pad;
the dielectric layers fill the spaces between the conductive layers; and
each soldering ball is formed on a bottom surface of the corresponding conductive layer.

16. The fan-out wafer level packaged chip structure according to 15, wherein:
the conductive layers have a single-level or a multiple level structure.

17. The fan-out wafer level packaged chip structure according to 15, wherein:
the packaging layer is made of a non-epoxy resin.

18. The fan-out wafer level packaged chip structure according to 15, wherein:
the soldering balls are made of Sn.
